(19) United States
(12) Patent Application Publication
(10) Pub. No.: US 2016/0313072 A1
(43) Pub. Date: Oct. 27, 2016

(54) HEAT SINK FOR COOLING PLURALITY OF HEAT GENERATING COMPONENTS

(71) Applicant: FANUC CORPORATION, Yamanashi (JP)

(72) Inventors: Kenichi Okuaki, Yamanashi (JP); Kazuhiro Yamamoto, Yamanashi (JP)

(73) Assignee: FANUC CORPORATION, Yamanashi (JP)

(21) Appl. No.: 15/080,690

(22) Filed: Mar. 25, 2016

(30) Foreign Application Priority Data
Apr. 27, 2015 (JP) 2015-090482

(51) Int. Cl. F28F 9/00; H01L 23/46; F28F 3/02

(52) U.S. Cl. CPC F28F 9/001; F28F 3/02; H01L 23/46

(57) ABSTRACT

A heat sink according to the present invention includes a heat receiving member which receives heat of heat generating components, a plurality of heat radiation fins arranged on the heat receiving member; and a cover member, which covers the plurality of heat radiation fins. Flow passages in which a fluid flows are formed between the adjacent heat radiation fins. The cover member is provided on the heat receiving member and opens both ends of the flow passages. The cover member is provided with at least one hole through which a fluid outside of the cover member is introduced into the fluid flowing in the flow passages.

### BACKGROUND OF THE INVENTION

1. Field of the Invention

The present invention relates to a heat sink for cooling a heat generating component, and in particular, it relates to a heat sink in which a plurality of heat generating components is arranged.

2. Related Art

Conventionally, a heat sink has been used to cool a heat generating component (e.g., refer to Japanese Patent No. 5043059 or Japanese Patent No. 4530054).

A conventional heat sink comprises a heat receiving member in which heat generating components are to be arranged and a plurality of heat radiation fins which are spaced from one another at predetermined distances and which are secured to the heat receiving member. Flow passages in which fluid flows are formed between the adjacent heat radiation fins. The flow passages have inlets and outlets. In such an arrangement, heat of the heat generating components is transmitted to the heat radiation fins through the heat receiving member. The heat thus transmitted to the heat radiation fins is radiated to the outside of the heat sink through the fluid flowing in the flow passages formed between the adjacent heat radiation fins.

In the conventional heat sink constructed as above, when a plurality of heat generating components are successively arranged on the heat receiving member along the length direction of the flow passages formed between the adjacent heat radiation fins, the following problems occur.

The fluid flowing in the flow passages receives heat from the heat receiving member or heat radiation fins during the movement from the upstream side to the downstream side, and accordingly, the temperature of the fluid increases. As a result, the temperature of the heat generating components arranged on the portion of the heat receiving member that corresponds to the downstream side of the flow passages (hereinafter referred to as “downstream side heat generating components”) tends to be higher than the temperature of the heat generating components arranged on the portion of the heat receiving member that corresponds to the upstream side of the flow passages (hereinafter referred to as “upstream side heat generating components”). Therefore, it is necessary for the downstream side heat generating components to have a higher heat resistance than the upstream side heat generating components. Furthermore, the location where the heat generating components can be placed may be restricted to avoid an increase of the temperature of the heat generating components. This results in an increase in the manufacturing cost of the devices including the heat generating components and the heat sink, and makes it difficult to design a device provided with the heat generating components.

### SUMMARY OF THE INVENTION

The present invention provides a heat sink which is capable of decreasing a temperature difference in the length direction of the flow passages in which fluid flows and which are formed in the heat sink.

According to the first aspect of the present invention, there is provided a heat sink for cooling a plurality of heat generating components, comprising a first surface provided with a first placement portion on which a first heat generating component is to be arranged and a second placement portion on which a second heat generating component is to be arranged, and a second surface opposite the first surface, a heat receiving member which receives heat of the heat generating components, a plurality of heat radiation fins arranged on the second surface, and a cover member which at least partly covers the plurality of heat radiation fins, wherein a flow passage in which a fluid flows is formed between adjacent heat radiation fins, the cover member opens both ends of the flow passage, and wherein the cover member is provided with at least one hole through which an external fluid outside of the cover member is introduced into the fluid flowing in the flow passage.

According to the second aspect of the present invention, there is provided a heat sink according to the first aspect, wherein the first and second placement portions are successively arranged along the length direction of the flow passage, and the hole is formed in the portion of the cover member that is located between the first placement portion and the second placement portion.

According to the third aspect of the present invention, there is provided a heat sink according to the first or second aspect, wherein the hole is formed along a line extending obliquely toward the downstream side of the flow passage with respect to a line perpendicular to an inner wall surface of the cover member.

According to the fourth aspect of the present invention, there is provided a heat sink according to any one of the first to third aspects, wherein the heat receiving member, the heat radiation fins and the cover member are formed integrally.

According to the fifth aspect of the present invention, there is provided a heat sink according to any one of the first to fourth aspects, further comprising a device which creates a flow of fluid passing in the flow passage in one direction.

According to the sixth aspect of the present invention, there is provided a heat sink according to any one of the first to fifth aspects, wherein the cover member is connected to the portion of each of the heat radiation fins opposite the heat receiving member, the flow passage being defined by a cavity surrounded by the heat receiving member, the heat radiation fins and the cover member.

The aforementioned objects, features and advantages and other objects, features and advantages of the present invention will become more apparent from the detailed description of the representative embodiments of the present invention illustrated in the accompanying drawings.

### BRIEF DESCRIPTION OF THE DRAWINGS

FIG. 1A is a perspective view of the structure of a heat sink according to the first embodiment.

FIG. 1B is a perspective view of the rear side of the heat sink shown in FIG. 1A.

FIG. 1C is a perspective sectional view of the heat sink taken along the line A-A in FIG. 1A.

FIG. 1D is a sectional view of the heat sink shown in FIG. 1A taken along the line A-A in FIG. 1A to illustrate the flow of the fluid.

FIG. 2A is a perspective sectional view of the structure of a heat sink according to the second embodiment.

FIG. 2B is a sectional view of the heat sink according to the second embodiment to illustrate the flow of the fluid.

FIG. 3A is a perspective sectional view of the structure of a heat sink according to the third embodiment.

FIG. 3B is a sectional view of the heat sink according to the third embodiment to illustrate the flow of the fluid.

FIG. 4A is a sectional view of a heat sink according to the fourth embodiment to illustrate the flow of the fluid.

FIG. 4B is a perspective view of the structure of the heat sink according to the fourth embodiment.

FIG. 4C is an enlarged partial view showing the shape of a communication port formed in the heat sink according to the fourth embodiment.

FIG. 5 is a sectional view of a heat sink according to the fifth embodiment to illustrate the flow of the fluid.

### DETAILED DESCRIPTION OF THE INVENTION

The embodiments of the present invention will be described below with reference to the drawings. In the drawings, the same reference numerals are assigned to the same or corresponding components. For the sake of easy understanding, the scale of the drawings was appropriately changed. Moreover, the drawings illustrate the heat sink of the present invention by way of example, and thus the present invention is not limited to the illustrated embodiments.

### First Embodiment

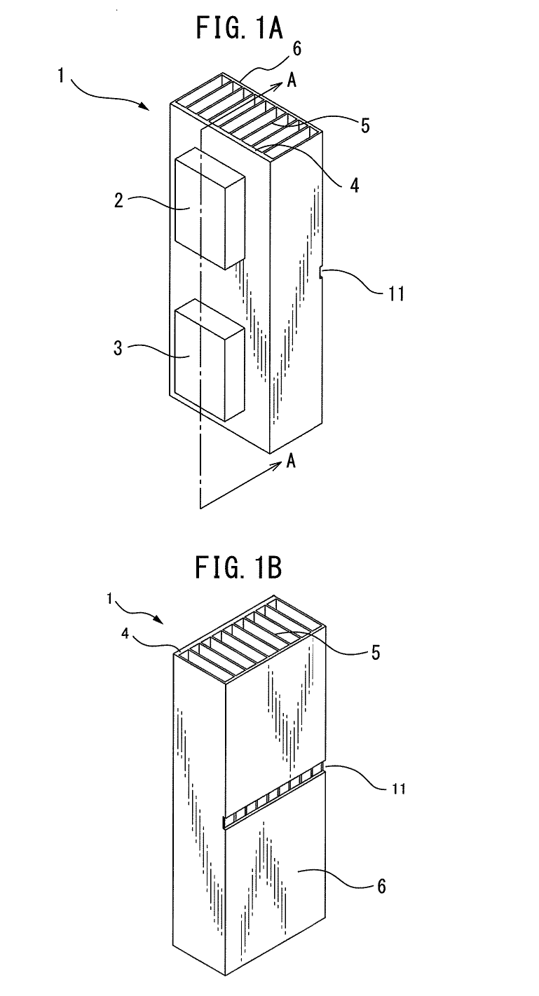

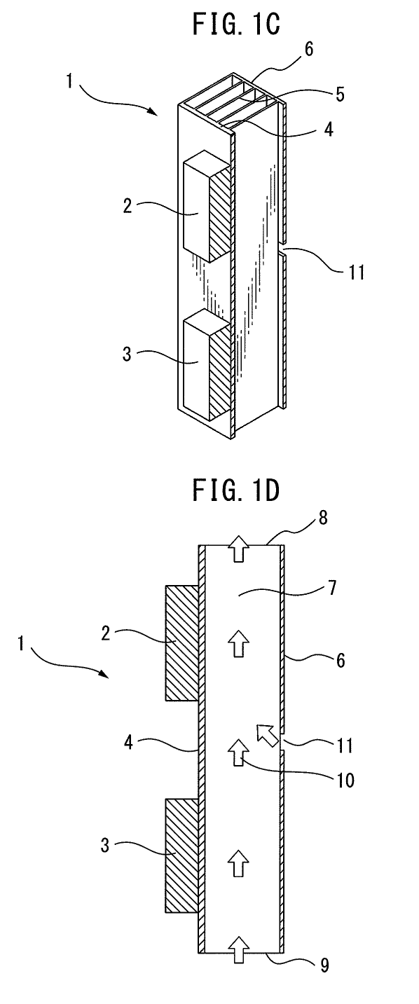

FIG. 1A is a perspective view showing the structure of the heat sink according to the first embodiment and FIG. 1B is a perspective view showing the rear side of the heat sink shown in FIG. 1A. FIG. 1C is a perspective sectional view of the heat sink taken along the line A-A in FIG. 1A, and FIG. 1D is a sectional view of the heat sink taken along the line A-A in FIG. 1A to illustrate the flow of the fluid.

With reference to FIGS. 1A to 1D, the heat sink 1 according to the first embodiment comprises a plate-like heat receiving member 4 which receives heat of a plurality of heat generating components 2, 3. The heat generating components 2, 3 are arranged on one (first surface) of two surfaces of the heat receiving member 4. The heat generating components 2, 3 may be semiconductor devices, such as IC, CPU, or IGBT, or light emitting devices such as LED or laser and are successively arranged along the longitudinal direction of the heat receiving member 4.

The other surface (second surface) of the heat receiving member 4 is provided with plate-like heat radiation fins 5. The heat radiation fins 5 are each in the form of a rectangular plate and are arranged to be perpendicular to the other surface of the heat receiving member 4. The heat radiation fins 5 extend from one end of the heat receiving member 4 in the longitudinal direction to the other end thereof. The plurality of heat radiation fins 5 are arranged in parallel and spaced from one another at predetermined distances.

A cover member 6 is provided to the other surface of the heat receiving member 4 to cover all the heat radiation fins 5. The portions of the heat radiation fins 5 opposite the heat receiving member 4 are proximate or connected to the cover member 6. Consequently, the heat receiving member 4, the heat radiation fins 5 and the cover member 6 define a cavity surrounded thereby. The cavity defines flow passages 7 in which fluid such as gas or liquid flows. The plurality of flow passages 7 are formed between the adjacent heat radiation fins 5. The fluid flows in each of the flow passages 7 as indicated by the arrows 10 in FIG. 1D. The heat receiving member 4, the heat radiation fins 5, and the cover member 6 are preferably made of a metal having a high thermal conductivity, such as aluminum or copper.

One end of each flow passage 7 defines an inlet 9 through which the fluid flows in and the other end defines an outlet 8 from which the fluid is discharged from the flow passage 7. The cover member 6 opens both ends of the flow passages 7.

In the illustrated embodiment, as can be seen in FIG. 1B, the cover member 6 is provided with one communication port 11 through which all of the flow passages 7 in the heat sink 1 communicate with the external space of the heat sink 1. As may be understood from FIG. 1B, the rectangular communication port 11 extends in a direction perpendicular to the length direction of the flow passages 7. As shown in FIG. 1D, the fluid outside of the heat sink 1 can enter each flow passage 7 through the communication port 11 formed in the cover member 6. Furthermore, the communication port 11 is formed in the portion of the cover member 6 that is located between the heat generating components 2 and 3, as may be seen in FIG. 1D.

As shown in FIGS. 1A to 1D, a plurality of placement portions on which the heat generating components 2, 3, etc., are to be placed are successively arranged on the heat receiving member 4 along the length direction of the flow passages 7. In this arrangement, if no communication port 11 is formed in the cover member 6, the fluid flowing in each flow passage 7 will absorb heat from the heat receiving member 4 and the heat radiation fins 5 during the movement from the upstream side toward the downstream side of the flow passage 7, and therefore the temperature of the fluid will increase. As a result, the temperature of the heat generating component 2 on the downstream side will become higher than the heat generating component 3 on the upstream side. Consequently, the temperature difference between the downstream side heat generating component 2 and the upstream side heat generating component 3 will increase.

In contrast thereto, in the present invention, the communication port 11 is formed in the intermediate portions of the flow passages 7 as shown in FIGS. 1A to 1D. Due to this, low temperature fluid outside of the heat sink 1 enters the flow passages 7 at the intermediate portions from the communication port 11 to cool the fluid in the fluid passages 7. Consequently, an increase of the temperature of the downstream side heat generating component 2 is suppressed, thus resulting in reduction of the temperature difference between the downstream side heat generating component 2 and the upstream side heat generating component 3.

In particular, as may be seen in FIG. 1D, the communication port 11 is formed in the area of the cover member 6 corresponding to the portion between the heat generating components 2 and 3, and accordingly, the fluid whose temperature has risen due to heat of the upstream side heat generating component 3 is cooled by the external fluid having a low temperature outside of the heat sink 1 and is thereafter moved to the area of the flow passages 7 corresponding to the downstream side heat generating component 2. Thus, it is possible to reliably prevent a temperature difference in the fluid from occurring in the length direction of the flow passages 7.

As may be understood from the foregoing, according to the first embodiment, in the heat sink 1 in which the plurality of heat generating components 2, 3 are successively arranged along the length direction of the flow passages 7 in which the fluid flows, the temperature difference in the length direction of the flow passages 7 can be reduced. Consequently, it is not necessary to use a material having a relatively high heat resistance for the downstream side heat generating component 2, and accordingly, it is possible to reduce the manufacturing cost of the device including the heat generating components 2 and 3 and the heat sink 1. Furthermore, as it is possible to prevent the temperature of the downstream side heat generating component 2 from increasing, there are less restrictions of the locations on which the downstream side heat generating component 2 can be arranged in an arrangement design.

Note that, the reason that the fluid outside of the cover member 6 flows in the flow passages 7 in the cover member 6 through the communication port 11 is as follows.

Namely, when the fluid outside of the cover member 6 enters the flow passages 7 from the inlet ports 9, the velocity of the fluid increases and the pressure in the flow passages 7 decreases. As a result, the pressure in the flow passages 7 becomes lower than the external pressure of the cover member 6, and consequently, the fluid outside of the cover member 6 enters the flow passages 7 through the communication port 11 of the cover member 6. This action occurs equally in both cases when the fluid is gas and is liquid.

Furthermore, when the fluid flowing in the flow passages 7 is gas, as shown in FIGS. 1A to 1D, it is preferable that the heat sink 1 be used in such a way that the longitudinal direction of the flow passages 7 is the vertical direction. When the fluid in the vertically extending flow passages 7 is heated by heat from the heat receiving member 4 or the heat radiation fins 5, an upward flow occurs due to natural convection in the flow passages 7. As a result, the fluid outside of the cover member 6 can be introduced into the flow passages 7 from the inlet ports 9 and discharged from the outlet ports 8 without using a special device. Furthermore, since the fluid flows occurs in the flow passages 7, the fluid outside of the cover member 6 is introduced into the flow passages 7 from the communication port 11 of the cover member 6 due to the aforementioned action. As a matter of course, the use of the heat sink 1 is not limited to the posture in which the length direction of the flow passages 7 is oriented vertically, as long as the upward flow is caused in the flow passages 7 due to the natural convection.

### Second Embodiment

The second embodiment will be described below. In particular, only the difference from the first embodiment will be described.

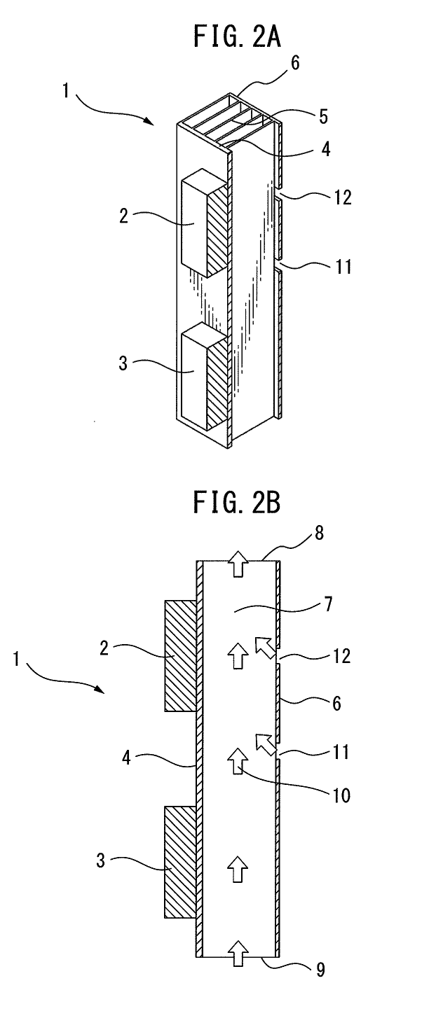

FIG. 2A is a sectioned perspective view of the heat sink according to the second embodiment. FIG. 2B is a sectional view of the heat sink according to the second embodiment to illustrate the flow of the fluid. FIGS. 2A and 2B correspond to modifications of FIGS. 1C and 1D used to explain the first embodiment mentioned above, respectively.

In the second embodiment, as can be seen in FIGS. 2A and 2B, the cover member 6 is provided with communication ports 11 and 12 (hereinafter respectively referred to as a first communication port 11 and a second communication port 12). The first communication port 11 is formed in the portion of the cover member 6 between the heat generating components 2 and 3 as in the aforementioned first embodiment. In the second embodiment, the second communication port 12 is formed in the portion of the cover member 6 between the outlet ports 8 and the first communication port 11. The remaining structures are the same as those of the first embodiment.

As mentioned above, the provision of the second communication port 12 makes it possible to further suppress an increase of the temperature of the downstream side heat generating component 2 compared with the first embodiment. As a result, the temperature difference between the downstream side heat generating component 2 and the upstream side heat generating component 3 can be made smaller in the second embodiment than in the first embodiment.

### Third Embodiment

The third embodiment will be described below. In particular, only the difference from the first embodiment will be described.

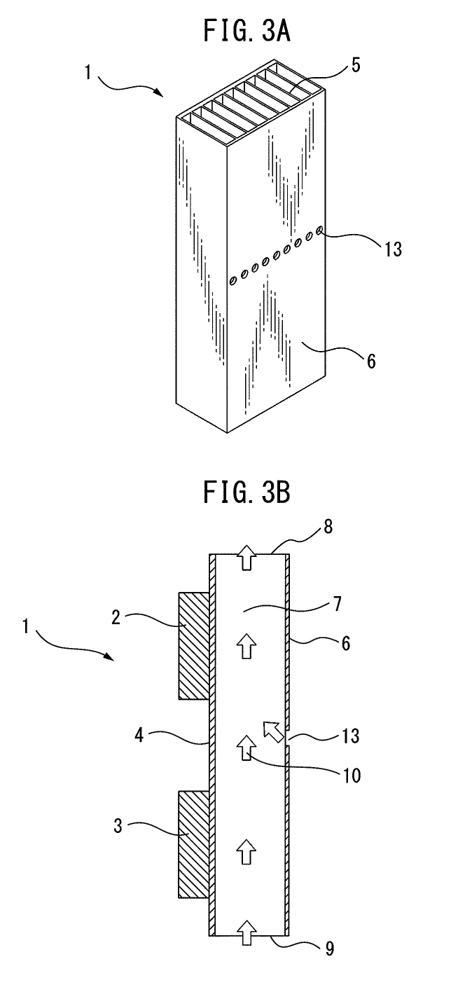

FIG. 3A is a perspective view of the heat sink according to the third embodiment. FIG. 3B is a sectional view of the heat sink according to the third embodiment to illustrate the flow of the fluid. FIGS. 3A and 3B correspond to modifications of FIGS. 1B and 1D used to explain the first embodiment mentioned above, respectively.

In the first embodiment, the cover member 6 shown in FIG. 1B is provided with the single communication port 11 through which the plurality of flow passages 7 communicate with the external space of the heat sink 1. In contrast thereto, in the third embodiment, the cover member 6 is provided with a plurality of communication ports 13 corresponding to the respective flow passages 7, as shown in FIGS. 3A and 3B. The plurality of communication ports 13 are successively arranged in a direction perpendicular to the length direction of the flow passages 7. The communication ports 13 are each made of a circular hole. The communication ports 13 are formed in the portion of the cover member 6 between the heat generating components 2 and 3 as in the first embodiment. The remaining structures are the same as those of the first embodiment.

According to the third embodiment, the same effects as the first embodiment can be brought about. Namely, it is not necessary to use a material having relatively high heat resistance for the downstream side heat generating component 2, and accordingly, it is possible to reduce the manufacturing cost of the device including the heat generating components 2 and 3 and the heat sink 1. Furthermore, as it is possible to prevent the temperature of the downstream side heat generating component 2 from increasing, there are less restrictions of the locations on which the downstream side heat generating component 2 can be arranged in an arrangement design.

Alternatively, an additional communication port(s) may be formed in the portion of the cover member 6 between the outlet port 8 and the communication ports 13, as in the aforementioned second embodiment (see FIGS. 2A, 2B). With this alternative arrangement, the temperature difference between the heat generating component 2 and the heat generating component 3 can be further reduced compared to the first embodiment.

Note that, in the third embodiment, the communication ports 13 are arranged in all of the flow passages 7 formed in the heat sink 1, but the communication port(s) 13 corresponding to at least one flow passage 7 appropriately selected from the plurality of flow passages 7 may be formed. Moreover, the communication ports 13 are each a circular hole in FIG. 3A, but the communication ports 13 may be holes having a shape other than a circular shape.

### Fourth Embodiment

The fourth embodiment will be described below. In particular, only the difference from the first embodiment will be described.

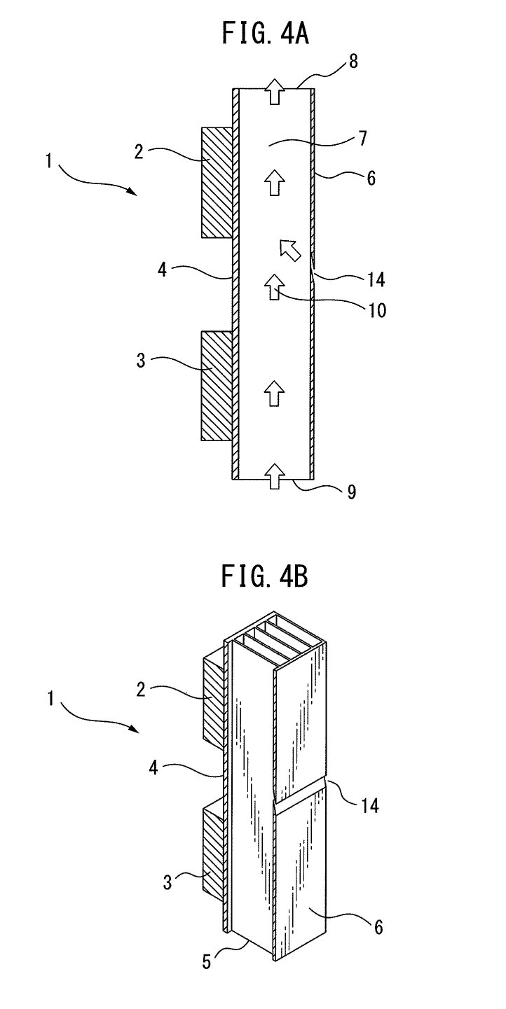

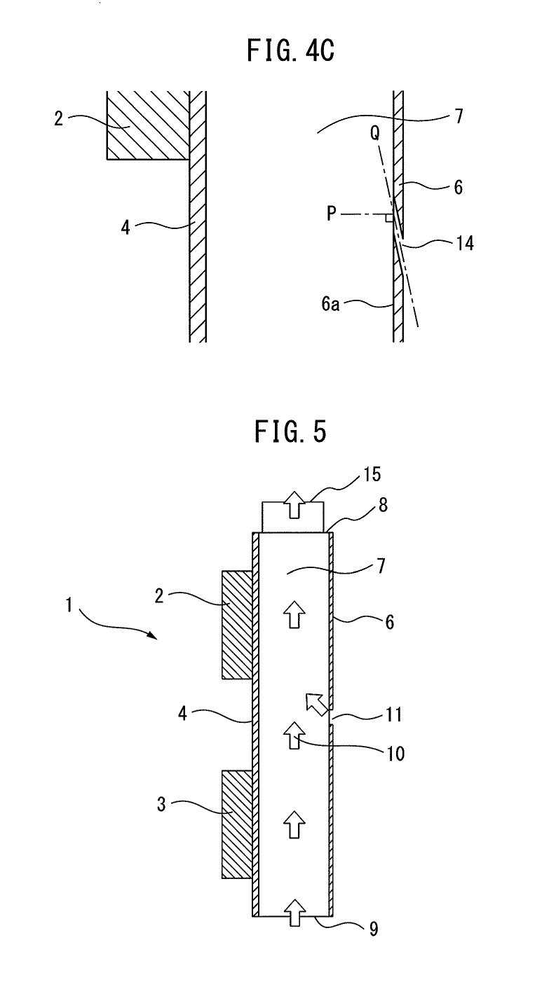

FIG. 4A is a sectional view of the heat sink according to the fourth embodiment to illustrate the flow of the fluid. FIG. 4B is a perspective view showing the structure of the heat sink according to the fourth embodiment. FIGS. 4A and 4B correspond to modifications of FIGS. 1D and 1C used to explain the first embodiment mentioned above, respectively.

In the fourth embodiment, a communication port 14 whose shape is different from the shape of the communication port 11 of the first embodiment is formed as can be seen in FIGS. 4A and 4B. Specifically, the communication port 11 of the first embodiment is in the form of a hole having a rectangular section, as shown in FIG. 1D, whereas, the communication port 14 of the fourth embodiment is in the form of a hole having a parallelogram section as shown in FIG. 4A. The remaining structures are the same as those of the first embodiment.

The communication port 14 of the fourth embodiment will be discussed below in detail.

FIG. 4C is an enlarged sectional view of a main part showing the shape of the communication port 14 formed in the heat sink according to the fourth embodiment.

In the fourth embodiment, as shown in FIG. 4C, the wall portion of the cover member 6 in which the communication port 14 is formed has a uniform thickness. The parallelogram sectional shape of the communication port 14 of the cover member 6 is defined by cutting the wall of the cover member 6 at the surfaces perpendicular to the inner surface of the heat receiving member 4 and at the parallel surfaces in the length direction of the flow passages 7. In particular, the communication port 14 is formed by a hole along the line Q which extends obliquely and downwardly of the flow passages 7 with respect to the line P perpendicular to the inner wall surface 6a of the cover member 6. With this arrangement, the flow of the fluid flowing in the flow passages 7 tends not to be disturbed by the fluid entering the flow passages 7 through the communication port 14.

In contrast, as the communication port 11 of the first embodiment illustrated in FIG. 1D is defined by a hole perpendicular to the inner wall surface of the cover member 6, the direction of the fluid entering the flow passages 7 through the communication port 11 is perpendicular to the stream of the fluid flowing in the flow passages 7. The fluid having such a flow direction through the communication port 11 may resist the fluid 10 flowing in the flow passages 7, thereby reducing the velocity of the fluid flow in the flow passages 7.

Therefore, in the fourth embodiment, the communication port 14 contributes to reducing the resistance to the fluid 10 flowing in the flow passages 7, compared with the communication port 11 of the first embodiment. Furthermore, as the velocity of the fluid in the flow passages 7 increases, the effect of cooling the fluid in the flow passages 7 can be enhanced. In addition thereto, according to the communication port 14 formed as shown in FIG. 4C, the effect that the flow passages 7 are less visible from the outside of the heat sink 1 can be brought about.

Note that, in the same manner as the aforementioned second embodiment, in the fourth embodiment, a communication port(s) may be formed in the portion of the cover member 6 between the outlet port 8 and the communication port 14, in addition to the communication port 11 (see FIGS. 2A and 2B). With this arrangement, the temperature difference between the heat generating component 2 and the heat generating component 3 can be reduced compared with the first embodiment.

### Fifth Embodiment

The fifth embodiment will be described below. In particular, only the difference from the first embodiment will be described.

FIG. 5 is a sectional view of the heat sink according to the fifth embodiment to illustrate the flow of the fluid.

In the fifth embodiment, a fan motor 15 is attached to the outlet port 8 of the fluid formed in the heat sink 1, as can be seen in FIG. 5. The fan motor 15 forcibly creates the fluid flow 10 as shown in FIG. 5. Namely, the fan motor 15 forcibly causes the fluid outside of the cover member 6 to be introduced into the flow passages 7 through the inlet ports 9 and the communication port 11 and to be discharged from the outlet ports 8. The remaining structures are the same as those of the first embodiment.

In particular, the provision of the fan motor 15 makes it possible for the low temperature fluid outside of the heat sink 1 to easily enter the flow passages 7 through the communication port 11, compared with the first embodiment. As a result, the effect that the temperature of the fluid which has increased in the flow passages 7 is decreased can be enhanced.

Note that, the place where the fan motor 15 is placed is not limited to the vicinity of the outlet ports 8 and the fan motor 15 may be placed in the intermediate portion of the flow passages 7, in the vicinity of the communication port 11 or the inlet ports 9. Furthermore, the device which forcibly creates the fluid flow 10 which passes in one direction in the flow passages 7 is not limited to the fan motor 15 and may be a rotary machine such as a pump or a compressor.

Moreover, as mentioned above, the technical idea of using a rotary machine such as a fan motor, pump or compressor is applicable to the heat sink 1 in any of the first to fourth embodiments regardless of whether the fluid to be introduced in the flow passages 7 is liquid or gas.

### Other Embodiments

The above description has been addressed to the first to fifth embodiments of the present invention by way of example, but the present invention is not limited to these embodiments.

The present invention may be applied to any arrangement in which even if the temperature of the fluid flowing in the flow passages of the heat sink increases due to heat of the heat generating components on the heat sink, the external fluid outside of the heat sink can be introduced into the flow passages at an intermediate portion of the flow passages so as to cool the fluid flowing in the heat sink. Therefore, it is only required that the heat sink of the present invention has a communication port through which the external fluid outside of the heat sink enters the flow passages in the heat sink. The optimum location, shape, size and number of the communication ports are variable and are determined depending on the size of the heat sink, the circumferential environment of the heat sink, or the number and arrangement of the heat generating components arranged on the heat sink, etc.

For instance, the structure of the heat sink 1 is not limited to those in the aforementioned embodiments, and may be an extruded structure in which the heat receiving member 4 and the heat radiation fins 5, and the cover member 6 are integrally formed. Alternatively, the heat sink 1 may have a structure in which the heat receiving member 4, the heat radiation fins 5 and the cover member 6 are integrated by brazing or caulking. With such an integral structure in which the heat receiving member 4, the heat radiation fins 5, and the cover member 6 are integrally formed, it is possible not only to obtain relatively high heat radiability less expensively but also reduce the number of components.

Moreover, the heat radiation fins 5 are not limited to those of the first to fifth embodiments in which each radiation fin is made of a single rectangular plate. For example, one radiation fin 5 may be divided into a plurality of heat radiation portions. Furthermore, the cover member 6 may be configured to at least partially cover a plurality of heat radiation fins 5, provided that the cavity surrounded by the plate-like heat receiving member 4, the heat radiation fins 5 and the cover member 6 defines the flow passages 7, as in the aforementioned embodiments. With this arrangement, the flow passages 7 having a relatively low resistance, i.e., a low pressure loss can be formed. As a result, the velocity of the fluid flowing in the flow passages 7 tends to not decrease and accordingly, the effect of absorbing heat of the heat receiving member 4 and the heat radiation fins 5 by the fluid flowing in the flow passages 7 can be enhanced.

### Effect of the Invention

According to the first aspect of the present invention, when the fluid flows in the flow passages formed between the adjacent heat radiation fins on the heat receiving member, a low temperature fluid outside of the cover member can be introduced into the flow passages through the hole(s) formed in the cover member which covers the heat radiation fins. Therefore, if the temperature of the fluid increases due to heat of the heat receiving member or the heat radiation fins during passage in the flow passages from the upstream side toward the downstream side, it is possible to lower the temperature of the fluid in the flow passages at the intermediate portion of the flow passages. Consequently, the temperature difference between the upstream side fluid and the downstream side fluid in the length direction of the flow passages can be lowered. As the temperature of the fluid on the upstream side of the flow passages is prevented from increasing, it is not necessary to use a component having a relatively high heat resistance as the downstream side heat generating component. Therefore, it is possible to reduce the manufacturing cost of the device including the heat generating components and the heat sink. Moreover, as an increase in the temperature of the downstream side heat generating component can be suppressed, there are fewer restrictions to the location where the heat generating components can be arranged when designing the devices.

According to the second aspect of the present invention, when a plurality of locations for the heat generating components are successively arranged on the heat receiving member in the length direction of the flow passages, a low temperature fluid outside of the heat sink can be introduced into the portions of the flow passages between the upstream side heat generating component and the downstream side heat generating component. Thus, the fluid whose temperature has increased due to heat of the upstream side heat generating component is cooled and is thereafter supplied to the portions of the flow passages corresponding to the downstream side heat generating component, thus leading to further enhancement of the effect of the first aspect.

According to the third aspect of the present invention, as the direction of the hole(s) through which the fluid outside of the cover member is introduced in the flow passages is inclined from the upstream side of the flow passages toward the downstream side, the flow of the fluid flowing in the flow passages is less disturbed by the fluid entering the flow passages through the hole(s). Consequently, it is possible to prevent the velocity of the fluid flowing in the flow passages from being reduced, and accordingly, the cooling effect of the fluid in the flow passages can be maintained in spite of the presence of the hole(s) in the cover member. In addition to the foregoing, the oblique hole(s) makes the inside of the flow passages less visible from the outside of the heat sink.

According to the fourth aspect of the present invention, as the heat receiving member, the heat radiation fins, and the cover member are formed integrally, not only can a relatively high radiability be inexpensively obtained but also the number of the components can be reduced.

According to the fifth aspect of the present invention, as a device which forcibly creates the fluid flow passing in the flow passages in one direction is provided, a low temperature fluid outside of the cover member can easily enter the flow passages, thus resulting in an enhancement of the cooling effect of the fluid in the flow passages.

According to the sixth aspect of the present invention, as the cavity surrounded by the heat receiving member, the heat radiation fins and the cover member defines the flow passages, the flow passages have a low resistance, i.e., a low pressure loss, whereby the velocity of the fluid flowing in the flow passages tends not to slow, thus resulting in the enhancement of absorbing heat from the heat receiving member or the heat radiation fins by the fluid flowing in the flow passages.

Note that the above description has been applied to the representative embodiments, but the present invention is not limited to the aforementioned embodiments and can be variously modified in the shape, structure or material, etc., without departing from the scope of the spirit of the invention.

What is claimed is:

1. A heat sink for cooling a plurality of heat generating components, comprising a first surface provided with a first placement portion on which a first heat generating component is to be arranged and a second placement portion on which a second heat generating component is arranged, and a second surface opposite the first surface,
the heat sink comprising:
a heat receiving member which receives heat of the heat generating components;
a plurality of heat radiation fins arranged on the second surface; and
a cover member which at least partly covers the plurality of heat radiation fins,
wherein: a flow passage in which a fluid flows is formed between adjacent heat radiation fins, the cover member opens both ends of the flow passage, and
the cover member is provided with at least one hole through which an external fluid outside of the cover member is introduced into the fluid flowing in the flow passage.

2. The heat sink according to claim 1, wherein the first and second placement portions are successively arranged along the length direction of the flow passage, and
the hole is formed in the portion of the cover member that is located between the first placement portion and the second placement portion.

3. The heat sink according to claim 1, wherein the hole is formed along a line extending obliquely toward the downstream side of the flow passage with respect to a line perpendicular to an inner wall surface of the cover member.

4. The heat sink according to claim 1, wherein the heat receiving member, the heat radiation fins and the cover member are formed integrally.

5. The heat sink according to claim 1, further comprising a device which creates a flow of fluid passing in the flow passage in one direction.

6. The heat sink according to claim 1, wherein the cover member is connected to the portion of each of the heat radiation fins opposite the heat receiving member, the flow passage being defined by a cavity surrounded by the heat receiving member, the heat radiation fins and the cover member.
